(19) United States
(12) Patent Application Publication
(10) Pub. No.: US 2005/0083082 A1
(43) Pub. Date: Apr. 21, 2005

(54) Retention device for a dynamic logic stage

(75) Inventor: Andreas Olofsson, Tel Aviv (IL)

Correspondence Address: Steven J. Henry;Wolf, Greenfield & Sacks, P.C., 600 Atlantic Avenue, Boston, MA, 02210, US

(73) Assignee: Analog Devices, Inc., Norwood, MA (US)

(21) Appl. No.: 10/688,156

(22) Filed: Oct. 15, 2003

(51) Int. Cl. H03K 19/096

(52) U.S. Cl. 326/95

(57) ABSTRACT

A retention device stabilizes the logic output levels of a dynamic logic stage. The dynamic logic stage contains an inverter, which generates an inverted logic signal that is used as a feedback signal into the retention device. The retention device contains a switching element consisting of two active elements connected in series. The retention device has two inputs, a control input for receiving a delayed clock signal, and a feedback input for receiving the inverted logic signal generated by the inverter. The feedback and delayed clock signals switch the switching element between two retention states, where each retention state stabilizes a respective logic output level.

### FIELD AND BACKGROUND OF THE INVENTION

The present invention relates to a retention device for a dynamic logic stage and, more particularly, to a self-timed strong retention device.

Dynamic logic is a circuit design technique used to increase digital circuit speed compared to static complementary metal oxide semiconductor (CMOS) logic. A CMOS gate is a fully complementary logic gate (using p-type and n-type devices configured to implement a desired logic function). Static CMOS logic gates require large fan-in, causing large gate input capacitances which slow down the logic circuit. Furthermore, static logic gates use slow p-type metal oxide semiconductor (PMOS) devices to implement a pull-up network, which further increase the capacitance of the gate input and slows rise times.

In dynamic logic circuits the PMOS pull-up network is replaced by a single clocked PMOS transistor. Each clock cycle is divided into two phases, a precharge phase and an evaluate phase. During the precharge phase, the output node is unconditionally precharged to a high logic state. During the evaluate phase the output node either remains high or is conditionally discharged to low, depending on the current logic output level. The logic function is implemented by a network of n-type transistors, which are controlled by the gate inputs in order to maintain or discharge the voltage at the output node.

FIG. 1 illustrates a typical prior-art dynamic logic circuit 100. The clocked input into the PMOS pull-up transistor 110 charges output node N_{OUT} to high during the precharge phase (clock signal is low), and releases N_{OUT} for conditional discharge during the evaluate phase (clock signal is high). The desired logic function (in this case {overscore ((A+B)*C))} is implemented by a network of n-type metal oxide semiconductor (NMOS) transistors 120. The dynamic logic circuit may also contain an optional NMOS pull-down transistor 130.

The dynamic logic circuit described above is comparatively sensitive to noise, with a noise margin significantly lower that that of the equivalent static CMOS logic gate. Since there is no longer a strong pull-up device to provide a high logic level during the evaluation phase, but merely the memory of the precharge value that was left from the precharge phase, dynamic circuits are very sensitive to glitches at the inputs and at the outputs. Although the increased sensitivity makes the gate faster, it also means that the power supply differential between the drivers of the logic inputs and the gate itself, along with any capacitive coupling induced noise, must be less than the input noise threshold. In fact, if the output node of the dynamic gate discharges by mistake, there is no way for the output node to return to a high state during the evaluation phase, no matter how slow the clock is. This means that all inputs to dynamic gates must be stable or monotonically rising during the evaluation phase. (Monotonically rising means that during the evaluation phase the dynamic gate inputs are allowed to make only low to high transitions.)

A consequence of this monotonicity limitation is that dynamic logic stages, as shown in FIG. 1, will not work if connected sequentially, since the precharged output of the first gate would by default discharge the second gate before the correct logic value arrives and causes the discharge to seize. A solution to this problem, suggested twenty years ago by Krambeck, Lee, and Law, is to place an inverter between each stage of dynamic logic. Krambeck et al.'s solution is illustrated in FIG. 2, which shows two dynamic logic gates 210 and 220 connected by inverter 230. This circuit design is generally referred to as domino logic.

Replacing half of the logic network in the static CMOS gate with a single PMOS transistor significantly reduces the problems of input capacitance and logic gate threshold. Since there is no longer contention between the pull-up network and the pull-down network during the time of evaluation, the logic threshold of the logic gate is reduced. Additionally, since each logic gate now only has to drive the NMOS portion of the logic gate, the capacitive load is generally reduced to less than half the capacitance of an equivalent static logic circuit.

Charge sharing between the weakly retained N_{OUT} output node and logic stage internal nodes can also cause glitches on N_{OUT}. These glitches may occur if some of the upper transistors in the evaluation tree are turned on during evaluation, while some of the lower transistors are not. For example, in FIG. 1, if A and B go high during evaluation while C stays low, the charge on N_{OUT} left from the precharge phase is redistributed between N_{OUT} and the node between the A, B, and C transistors.

Another disadvantage of domino logic circuits is that leakage currents flow through the transistors that form the logic network, even when the n-type transistors should be off. A high value at the dynamic output may thus be pulled down to a low value over time, causing loss of data. One approach to compensating for the leakage current is to use a retention device, known as a keeper. A typical keeper circuit, known as a half keeper, is shown in FIG. 1. Half keeper 140 includes an inverter 150 and a p-type transistor 160, with the inverter output coupled to the gate of the p-type transistor 160, and the drain of the p-type transistor 160 feeding back into N_{OUT}. The source of the p-type transistor 160 is coupled to a positive power supply voltage, V_{DD}. Thus, when the dynamic output of the domino logic circuit is high, the p-type transistor 160 of the keeper circuit is on, further charging the dynamic output of the domino logic circuit to high. When the dynamic output of the domino logic circuit is low, the p-type transistor 160 of the keeper circuit is off, allowing the dynamic output of the domino logic circuit to discharge to a low logic level.

The problem of leakage-induced voltage drops is becoming more acute along with the advances in MOS transistor scaling. In extremely short channel device metal oxide semiconductor field effect transistor (MOSFET) technology, such as 0.13 um, leakage currents are becoming significant relative to the saturation current of the transistor, sometimes reaching 0.1%. These large leakage currents discharge the logic gate output node rapidly, causing a critical problem for medium and low frequency operations which have a relatively long duration evaluate phase.

In wide fan-in dynamic circuits such as register files and zero detection circuits, in which many NMOS discharge devices are connected in parallel, leakage currents can become significant. The half-keeper described above is capable of maintaining the voltage level at N_{OUT} for low leakage currents, but fails as the leakage currents increase. In order to combat increased current leakage, a stronger transistor must be used in the keeper circuit. However, increasing transistor strength increases capacitance and slows the gate response time. The driver strength of the traditional keeper is bounded, as it must be weak enough to allow the pull-down network to complete a potential high-to-low transition, but strong enough to combat all the leakage current in the pull-down network. Designing a keeper strong enough to combat leakage problems but not so strong as to slow down the discharge path has proven to be problematic.

In many cases, the solution has been to simply limit the number of inputs to each dynamic logic stage. To obtain dynamic logic stages with greater fan-in, several of the limited fan-in gates are combined. Reference is now made to FIG. 3, which shows two N-wide sub-multiplexers, 310 and 320, which are combined to form a 2N-wide multiplexer 300. Sub-multiplexers 310 and 320 operate in parallel. Each sub-multiplexer has N data inputs, D1 to D2N (inputs D1 to DN for sub-multiplexer 310 and inputs D(N+1) to D2N for sub-multiplexer 320), and N select inputs (inputs SEL1 to SELN for sub-multiplexer 310 and inputs SEL(N+1) to SEL2N for sub-multiplexer 320). Only one of the 2N select inputs is on at any given time, so that one of the sub-multiplexers has a data input selected and the other sub-multiplexer is turned off. NAND gate 330 combines the two sub-multiplexer outputs, and outputs the selected data signal at N_{OUT}. It is seen that combining limited fan-in elements to form wide fan-in gates requires significant duplication of circuit hardware (such as separate pull-up transistors and keepers for each element), as well as the addition of circuitry in order to combine the limited fan-in elements into a wide fan-in gate.

A second prior-art solution to resolving the conflict between the need for a stronger keeper and the resulting speed problems is presented by Bhushan et al. in U.S. Pat. No. 6,559,680. Bhushan et al. provide a data driven keeper for a domino device which has additional keeper transistors associated with the logic inputs. The additional keeper transistors are selectively activated when one of the logic network input transistors has a low or inactive signal applied to it during the evaluation phase. The additional keepers reduce current leakage through the logic network, thereby improving the soft error rate. Bhutan et al.'s keeper circuitry is problematic, as it requires an additional keeper transistor for each logic input. The number of additional transistors grows as the number of inputs to the gate increase, and can become substantial for wide fan-in logic gates.

An alternative keeper for a wide fan-in dynamic logic gate is shown by Alvandpour, et al. in U.S. Pat. No. 6,549,040. Alvandpour et al. use a minimum sized keeper in parallel with a stronger keeper. FIG. 4 herein shows an example of an M-wide multiplexer gate 400 with the strong keeper proposed by Alvandpour, et al. Aside from the strong keeper 440, all other circuit elements (pull-up transistor 410, logic network 420, and weak keeper 430) function similarly to those discussed above. The strong keeper 440, is formed from a NAND gate and an n-type transistor, and is switched by a delayed clock signal. Keeper 440 starts working only after the discharge phase has been completed. The delay element for the strong retention device is long enough not to cause contention and short enough that a significant leakage related voltage drop does not occur at N_{OUT}. Although the keeper 440 of FIG. 4 is capable of enlarging dynamic gate fan-in, this increase is obtained at the cost of increased hardware, which increases the dynamic gate area and power consumption.

In U.S. Pat. No. 6,255,854, Houston presents a feedback stage for protecting a dynamic node in an integrated circuit having dynamic logic. An integrated circuit dynamic logic stage is disclosed that includes a dynamic node. A feedback stage protects the dynamic node and includes a controllable current path connected between a voltage supply and the dynamic node, where the controllable current path has a control terminal. The feedback stage also includes a feedback path from the dynamic node to the control terminal, where the feedback path includes a delay stage providing a delay greater than intrinsic circuit delay. The feedback stage protects the dynamic node against an upset pulse using a keeper transistor that is smaller than that possible with conventional protection schemes, so that the dynamic logic stage pulls against a smaller keeper transistor. Additionally, the problem of bipolar leakage that can upset dynamic nodes in floating body silicon-on-insulator designs is reduced. However, the feedback stage presented by Houston does not remove the contention between the NMOS pull-down device and the PMOS pull-up device during the discharge phase, but rather reduces it. This contention slows down the gate and thus is sub-optimal in terms of speed. A second problem is that an accumulation mode transistor is required to ensure that the node between the PMOS pull-up device and the NMOS pass gate is completely turned off. The use of an accumulation transistor is not readily available in all processes, and can prove costly when it is available.

In summary, wide fan-in domino gate logic gates are important elements for the design of many systems, including memory, control, and wide arithmetic units. Wide fan-in gates often generate fewer logic levels, which in turn can result in compact, high-performance, and relatively low power circuits. The increasing leakage currents of sub-micron width transistors are severely limiting to the performance, robustness, and consequently to the practical use of domino circuits. The conventional solution involves a trade-off between robustness and performance, and has difficulty handling relatively large leakage in wide domino stages created by low threshold voltage sub-micron devices. Other proposed solutions effectively stabilize the logic output voltage levels, but at the cost of increased hardware, and consequently the area and power required by the keeper circuitry.

The sensitivity of dynamic logic circuits to leakage currents, noise levels and noise spikes has in many cases limited the use of dynamic logic circuits, despite their speed and other advantages. Since the probability of not completely preventing the failure mechanisms mentioned above is directly proportional to the number of gates designed, dynamic logic usage is often limited to those critical paths that have been clearly identified during the module definition and architecture stage, and to specific instances for which the environment can be carefully controlled, such as adders, multipliers and carefully planned custom data paths. Improving dynamic circuit output stability will extend the practical application of dynamic logic to a broader class of circuit architectures, and to less carefully controlled operating environments.

There is thus a widely recognized need for, and it would be highly advantageous to have, a dynamic logic retention device devoid of the above limitations.

### SUMMARY OF THE INVENTION

According to a first aspect of the present invention there is provided a retention device which stabilizes the logic output levels of a dynamic logic stage. The dynamic logic stage contains an inverter, which generates an inverted logic signal that is used as a feedback signal into the retention device. The retention device contains a switching element consisting of two active elements connected in series. The retention device has two inputs, a control input for receiving a delayed clock signal, and a feedback input for receiving the inverted logic signal generated by the inverter. The feedback and delayed clock signals switch the switching element between two retention states, where each retention state stabilizes a respective logic output level.

According to a second aspect of the present invention there is provided a retention device which stabilizes the logic output levels of a dynamic logic stage. The retention device contains a switching element consisting of two active elements connected in series. The retention device has two inputs, a control input for receiving a delayed clock signal, and a feedback input for receiving the dynamic logic stage logic output signal. The feedback and delayed clock signals switch the switching element between two retention states, where each retention state stabilizes a respective logic output level.

According to a third aspect of the present invention there is provided a stabilized dynamic logic stage. The dynamic logic stage consists of a pull-up element, a logic network, an inverter, and a retention device. The pull-up element switches the stabilized dynamic logic stage between a precharge phase and an evaluate phase in accordance with an input clock signal. The logic network evaluates the logic inputs in accordance with a specific logic function determined by the arrangement of the logic network components, and provides the resulting logic signal to the logic output of the dynamic logic stage. The inverter generates an inverted logic signal that is used as a feedback signal into the retention device. The retention device stabilizes the output levels of the logic stage during the evaluation phase. The retention device contains a switching element consisting of two active elements connected in series. The retention device has two inputs, a control input for receiving a delayed clock signal, and a feedback input for receiving the inverted logic signal generated by the inverter. The feedback and delayed clock signals switch the switching element between two retention states, where each retention state stabilizes a respective logic output level.

According to a fourth aspect of the present invention there is provided a method for providing a stabilized dynamic logic stage. The method consists of the following steps. First a pull-up element is provided. The pull-up element has a clock input for receiving a clock signal, and a pull-up output. A logic output of a logic network is then connected to the pull-up output, the logic network having multiple logic inputs. Next, an inverter is connected to the logic output and the pull-up element, so that the inverter input is connected to the logic output. In the following step, a switching element is formed by connecting two active elements in series. The switching element is then connected between the inverter and the logic network. The switching element has two inputs, a feedback input and a control input, and a single output. The output of the switching element is connected to the logic output, and the feedback input of the switching element is connected to the inverter output. Finally, the control input of the switching element is connected in a manner that enables it to receive a delayed version of the clock signal.

The present invention successfully addresses the shortcomings of the presently known configurations by providing a self-timed strong retention device.

Unless otherwise defined, all technical and scientific terms used herein have the same meaning as commonly understood by one of ordinary skill in the art to which this invention belongs. Although methods and materials similar or equivalent to those described herein can be used in the practice or testing of the present invention, suitable methods and materials are described below. In case of conflict, the patent specification, including definitions, will control. In addition, the materials, methods, and examples are illustrative only and not intended to be limiting.

Implementation of the method and system of the present invention involves performing or completing selected tasks or steps manually, automatically, or a combination thereof. Moreover, according to actual instrumentation and equipment of preferred embodiments of the method and system of the present invention, several selected steps could be implemented by hardware or by software on any operating system of any firmware or a combination thereof. For example, as hardware, selected steps of the invention could be implemented as a chip or a circuit. As software, selected steps of the invention could be implemented as a plurality of software instructions being executed by a computer using any suitable operating system. In any case, selected steps of the method and system of the invention could be described as being performed by a data processor, such as a computing platform for executing a plurality of instructions.

### BRIEF DESCRIPTION OF THE DRAWINGS

The invention is herein described, by way of example only, with reference to the accompanying drawings. With specific reference now to the drawings in detail, it is stressed that the particulars shown are by way of example and for purposes of illustrative discussion of the preferred embodiments of the present invention only, and are presented in the cause of providing what is believed to be the most useful and readily understood description of the principles and conceptual aspects of the invention. In this regard, no attempt is made to show structural details of the invention in more detail than is necessary for a fundamental understanding of the invention, the description taken with the drawings making apparent to those skilled in the art how the several forms of the invention may be embodied in practice.

In the drawings:

FIG. 1 is a circuit diagram of a typical prior art dynamic logic circuit with a weak keeper.

FIG. 2 is a circuit diagram of two prior art dynamic logic stages connected by inverter.

FIG. 3 is a circuit diagram of prior art limited fan-in gates combined in parallel.

FIG. 4 is a circuit diagram of an M-wide multiplexer gate with a prior art strong keeper.

FIG. 5 is a simplified block diagram of a retention device within a dynamic logic stage, according to a preferred embodiment of the present invention.

FIG. 6 is a simplified theoretical model of a retention device, according to a preferred embodiment of the present invention.

FIG. 7 is a simplified block diagram of a switching element, according to a preferred embodiment of the present invention.

FIGS. 8a and 8b are simplified circuit timing diagrams, according to a preferred embodiment of the present invention.

FIG. 9 is a simplified block diagram of a dynamic logic stage having an integral retention device, according to a preferred embodiment of the present invention.

FIG. 10 is a simplified block diagram of a retention device for a dynamic logic stage without an output inverter, according to a preferred embodiment of the present invention.

FIG. 11 is a simplified flowchart of a method for providing a stabilized dynamic logic stage, according to a preferred embodiment of the present invention.

### DESCRIPTION OF THE PREFERRED EMBODIMENTS

Dynamic logic circuits offer significant advantages over equivalent static CMOS logic circuits. Dynamic logic is both quicker and more area efficient than the equivalent static logic hardware. Unfortunately these advantages are gained at the cost of reduced stability of the logic outputs and increased sensitivity to noise. As a result, dynamic logic usage is often limited to critical signal paths and to carefully controlled operating conditions. Increasing the stability of these circuits would permit the use of dynamic logic in a wider spectrum of applications, and enable the development of faster, and more efficient systems.

One common technique for stabilizing the logic output of a dynamic circuit stage is to use a feedback retention device, known as a keeper, to maintain the circuit's logic output at the correct logic level during the evaluation phase. The present embodiments are of a retention device for a dynamic logic circuit that replaces the weak keeper commonly found in dynamic logic circuits with a stronger self-timed keeper.

The principles and operation of a retention device for a dynamic logic circuit according to the present invention may be better understood with reference to the drawings and accompanying descriptions.

Before explaining at least one embodiment of the invention in detail, it is to be understood that the invention is not limited in its application to the details of construction and the arrangement of the components set forth in the following description or illustrated in the drawings. The invention is capable of other embodiments or of being practiced or carried out in various ways. Also, it is to be understood that the phraseology and terminology employed herein is for the purpose of description and should not be regarded as limiting.

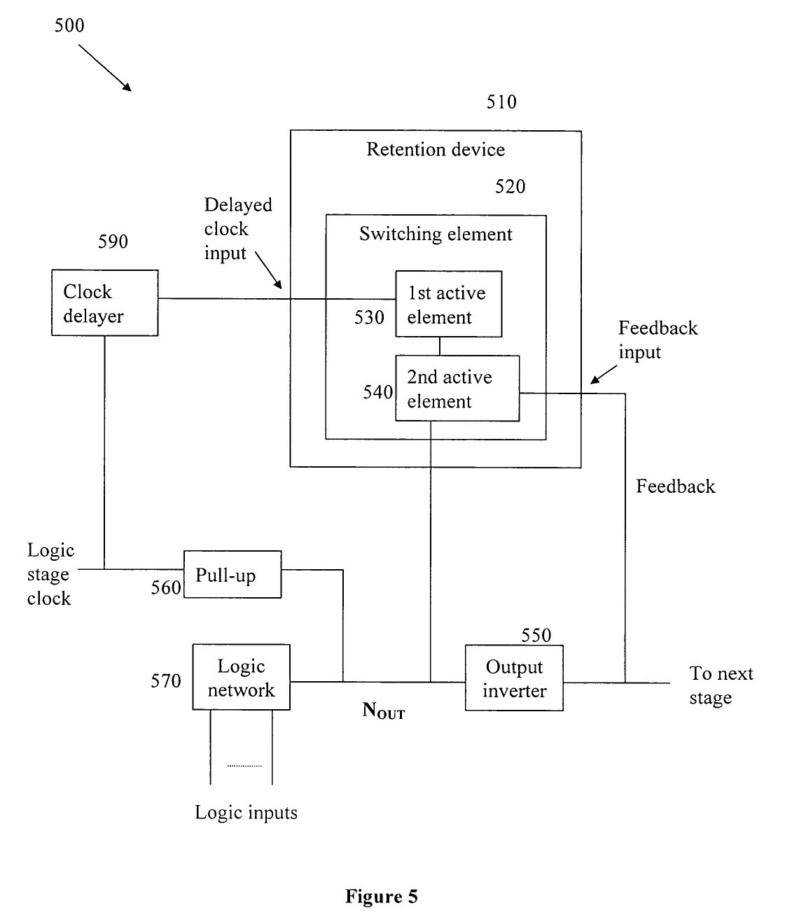

Reference is now made to FIG. 5, which is a simplified block diagram of a retention device which stabilizes the logic output levels of a dynamic logic stage, according to a preferred embodiment of the present invention. Retention device 510 is shown within dynamic logic stage 500. Retention device 510 comprises a switching device 520, consisting of two active elements, 530 and 540, connected in series. Retention device 510 has a control input and a feedback input, for receiving a delayed clock signal and a feedback signal respectively. The delayed clock signal is a delayed replica of the logic stage clock. The feedback signal is an inverted version of the logic stage output, and is provided by an output inverter 550. The feedback and delayed clock signals switch the retention device between two retention states.

Output inverter 550 is an element of the dynamic logic stage 500, and is located between the output node, N_{OUT}, and the feedback input of the retention device 510. In addition to the output inverter 550, dynamic logic stage 500 also contains pull-up element 560, and logic network 570, which function essentially as described above.

The present embodiment eliminates the weak keeper customarily found in dynamic logic retention devices, thus reducing the contention between the pull-down path and the retention path, and speeding up the circuit.

Preferably, switching device 520 is controlled by two control signals, a delayed replica of the logic stage clock, and a feedback signal consisting of the inverted version of the logic stage output provided by the output inverter 550. The delayed clock may consist of an inverted version of the logic stage clock or of a slightly delayed inverted version of the logic stage clock, as described below. In the preferred embodiment, active element 530 is switched by the delayed clock signal, whereas active element 540 is switched by the inverted logic feedback signal. (Note that the order of the active elements within the retention device 510 is not significant.) The retention device 510 output is connected to the logic stage output node, N_{OUT}.

The two control signals switch the output of the retention device 510 between two retention states. Each of the retention states stabilizes a different one of the two logic stage output levels. The first retention state provides strong retention of the high logic level, preferably by preventing the output node from discharging through the logic network during the evaluation phase. The second retention state stabilizes the low logic level, preferably by enabling the logic stage output node to discharge through the logic network during the evaluation phase.

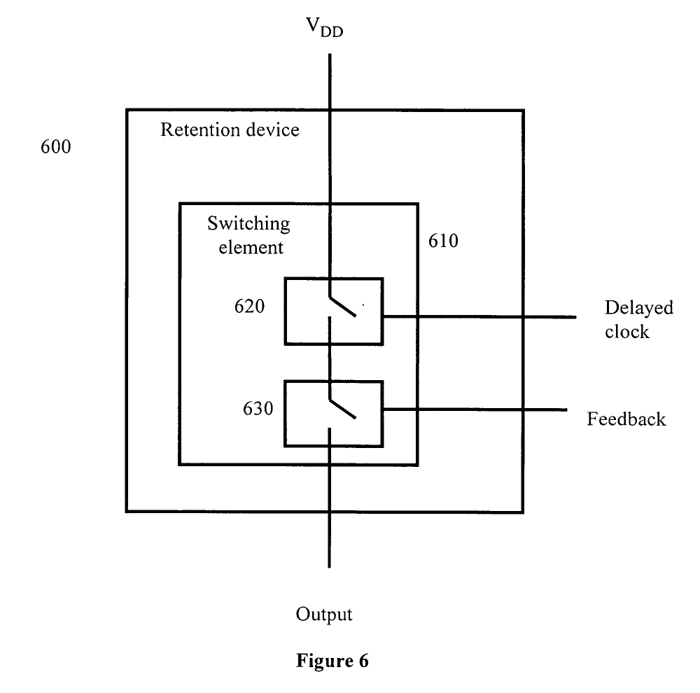

Reference is now made to FIG. 6, which shows a simplified theoretical model of a retention device, according to a preferred embodiment of the present invention. Retention device 600 comprises switching element 610, which contains two active elements, 620 and 630, connected in series. Both active elements are switches having a single control terminal. The delayed clock signal controls switch 620, while the inverted output feedback signal controls switch 630. Assume that both switches close when a low control signal is applied. If both the delayed clock and feedback signals are low, the retention device 600 connects N_{OUT} to V_{DD}. The logic stage output N_{OUT} is prevented from discharging to a low logic level, and retention device 600 is therefore in the first retention state. For all other combinations of control signals, one or both of switches 620 and 630 are open, and the retention device 600 effectively switches itself out of the logic stage. If the logic network (570 of FIG. 5) is low, N_{OUT} is free to discharge through the logic network, without interference by the retention device 600. The retention device 600 is therefore in the second retention state. Note that as long as the retention device remains in the second retention state, the dynamic logic stage operates as if the retention device 600 is not present.

In accordance with the theoretical model of FIG. 6, retention device 600 outputs a high logic level (such as a predetermined voltage level) when it is in the first retention state, and provides a high impedance at the retention device output when it is in the second retention state. It can be seen that retention device 600 does not influence the logic stage output level during the precharge phase. During the precharge phase N_{OUT} is pulled high by the pull-up element (560 of FIG. 5). If the retention device 600 is in the first retention state it reinforces the action of the pull-up element 560 by retaining the high voltage at N_{OUT}. If the retention device 600 is in the second retention state, the dynamic logic stage operates as if the retention device 600 is not present, and N_{OUT} is precharged as usual.

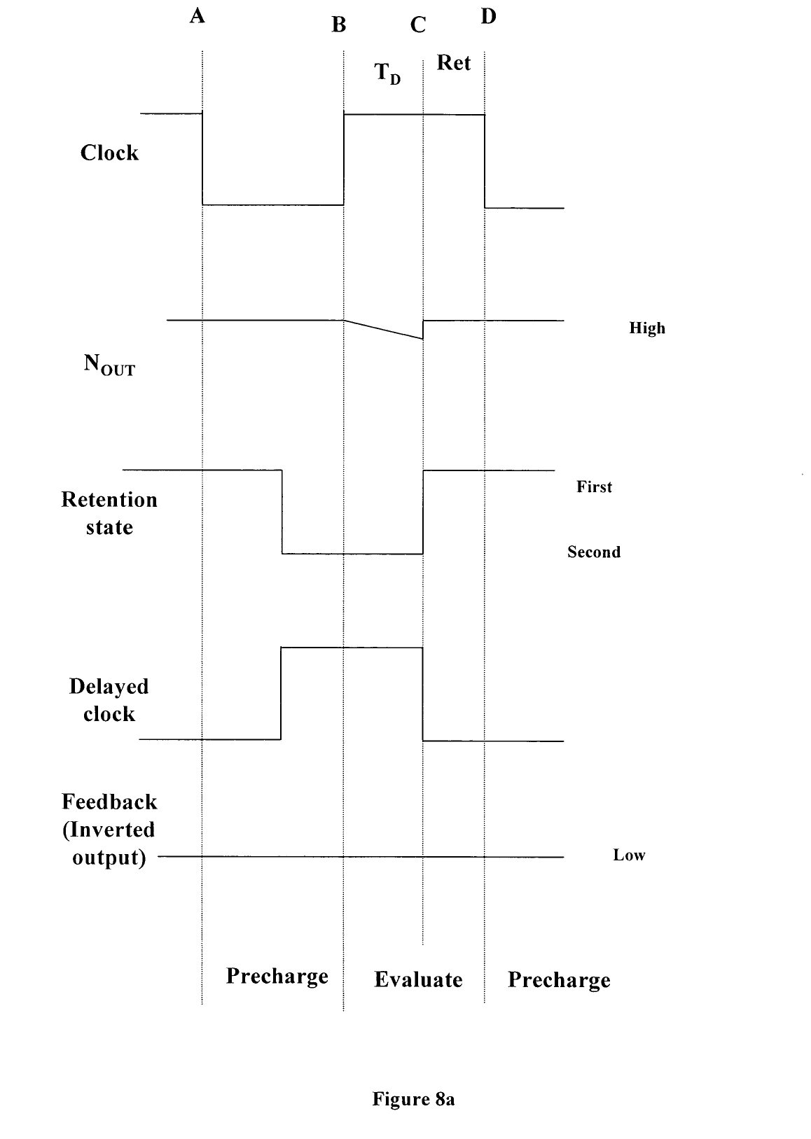

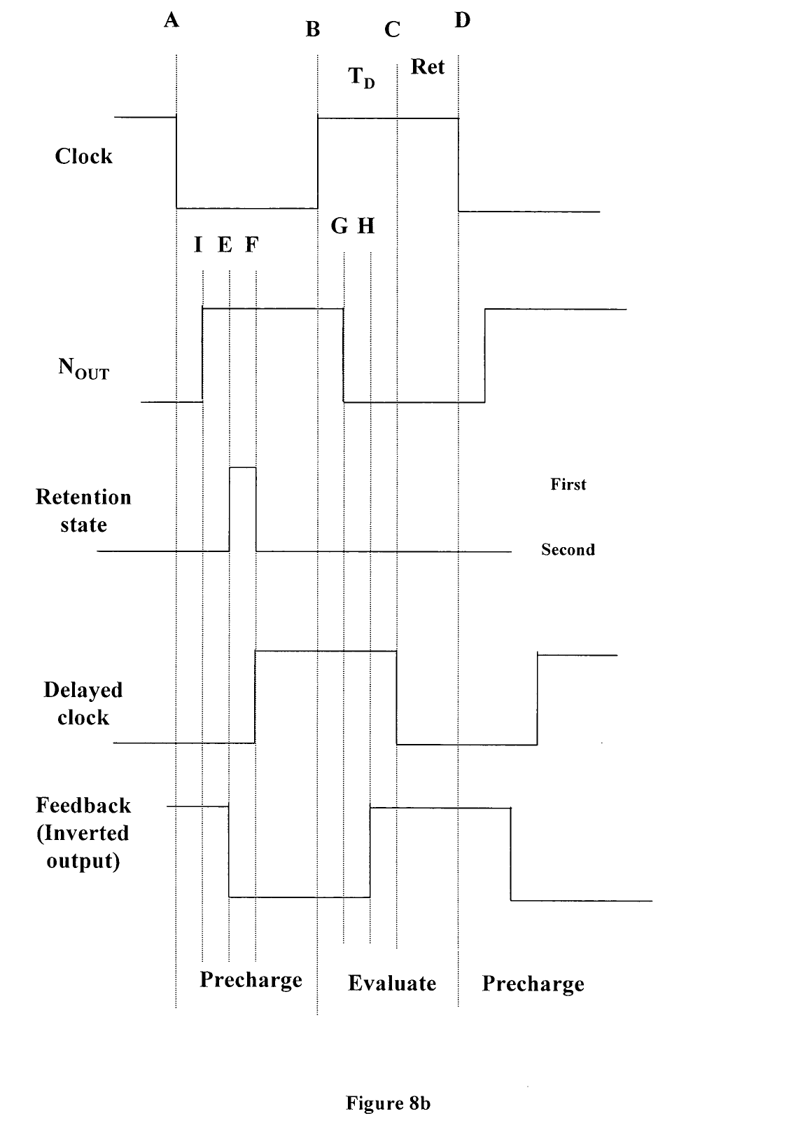

Retention device 600 influences the logic stage output level only during the evaluation phase. The evaluation phase can be divided into two regions, the evaluation region and the retention region. As shown below in FIGS. 8a and 8b, at the beginning of the evaluation phase the retention device is in the second retention state for the duration of a certain delay time, T_{D}. T_{D} is determined by the time delay between the logic stage clock and the delayed clock control signal. During the evaluation region the output node level stabilizes at a logic level established by the logic network. The retention region begins with the transition of the delayed clock. During the retention region, the retention device switches into a retention state associated with the current output node logic level. Once in the correct retention state, the retention device stabilizes the logic output level until the beginning of the next clock cycle.

The two control signals ensure proper timing of the retention device. The delay time between the logic stage clock and the delayed clock signal divides the evaluation phase into the evaluation and retention regions. The clock delay is timed so that logic level stabilization occurs after the logic output and feedback signals have stabilized, but before a high logic output level has time to discharge to low. The feedback signal provides the information about the current state of the dynamic logic stage, so that the retention device switches into the correct retention state for the duration of the retention region.

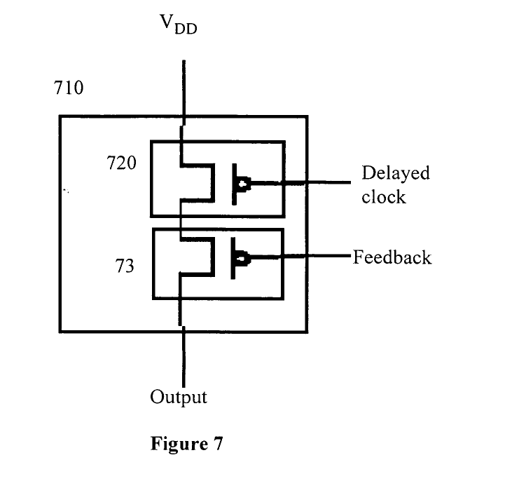

In the preferred embodiment, either or both of the active elements are transistors, in particular FETs or PMOS transistors. Reference is now made to FIG. 7, which is a simplified block diagram of a transistor-based switching element, according to a preferred embodiment of the present invention. Switching element 710 is made up of two PMOS transistors, 720 and 730, connected in series. PMOS transistor 720 is switched by a delayed clock signal consisting of an inverted version of the logic stage clock, and PMOS transistor 730 is switched by a feedback signal consisting of the inverse of the logic stage output. The retention device 700 is defined to be in the first retention state when the retention device output is V_{DD}, and to be in the second retention device for a high impedance output. For the current embodiment, the output of the retention device is V_{DD} only when both the feedback signal and the delayed clock are low. For all other inputs the retention device is in the second retention state.

Reference is now made to FIGS. 8a and 8b, which are timing diagrams showing the operation of the retention device of FIG. 7 with a logic stage. For purposes of this description, the switching element is assumed to be in the first retention state when both the delayed clock and feedback signals are low and in the second retention state for all other control signal levels, however other embodiments are possible. Note that signal rise and fall times are not shown. As the skilled person will appreciate, with proper timing of the feedback and control signals the signal rise times will not interfere with the proper functioning of the retention element.

FIG. 8a shows typical signal levels for a high logic output, so that the output node should remain high for the entire evaluate phase (time B to time D). Logic stage operation for a high output is as follows. At time A the logic stage clock falls, and begins the precharge phase. From time A until time B, the output node is pulled high by the pull-up element. As can be seen in the figure, at the end of the precharge phase the delayed clock is still high due to the time delay between the two clock signals. The retention device is therefore in the second retention state. While the retention device is in the second state the level of the output node falls slowly due to leakage current through the logic network. Note that the feedback signal remains low, since the inverter output does not switch to high unless the output node level has fallen below the inverter threshold.

The retention region begins at time C when the delayed clock signal goes low. Since both the delayed clock and the feedback signals are now low, the retention device switches to the first retention state and starts to stabilize the high output level. The retention device thereby provides strong retention of the high output level, under the condition that the evaluation region (B-C) is shorter than the time required for the high output to discharge to low. The retention device remains in the first retention state and until the beginning of the next precharge phase, at time D.

FIG. 8b shows typical signal levels when the logic stage output is low, so that the output node may discharge at the beginning of the evaluate phase (time B). Logic stage operation for a low output is as follows. The clock cycle begins at time A, when the logic clock falls and begins the precharge phase. The output node precharges during the first portion of the precharge phase, from time A-I, and is fully charged by time I. As described for FIG. 8a, the output node is precharged by the pull-up element until time B. (Note that for a portion of the precharge phase, E-F, both the feedback and delayed clock signals are low and the retention device is therefore in the first retention state. This does not affect the logic stage output, since, as discussed above, the retention device does not affect the logic stage output level during precharge.) As discussed above, at time B the retention device is in the second retention state, since the delayed clock is still high. The output node is therefore able to discharge through the logic network. At time G the output node has had sufficient time to discharge to low. After a brief delay, at time H, the inverter responds to the change in output node level and goes high. The high feedback signal from the inverter ensures that the retention device remains in the second retention state even after the delayed clock signal goes low at time C. Provided that the feedback signal goes high before the evaluation region (B-C) has ended, the retention device remains in the second retention state (i.e. discharged) for the entire evaluation phase.

Referring again to FIG. 5, in the preferred embodiment the retention device contains a clock delayer 590, which delays the logic stage input clock to generate the delayed clock signal that serves as the control signal to switching element 520. If a clock delayer is not present, the delayed clock signal is provided externally. Clock delayer 590 may consist of one or more inverters, one or more transmission gates, one or more wire delay lines, or a combination thereof. In some cases the required delayed clock signal is an inverse of the dynamic logic stage clock, and the clock delayer is a single inverter. In addition to the inverter, the clock delayer may also contain a fixed delay element which adds an additional delay to the inverted clock. Delay element 590 tracks the domino evaluation delay as closely as possible over all process and operating corners. A single delayed clock signal may be used for several logic stages, as long as the timing of the delayed clock signal enables proper operation of the retention devices in all of the logic stages.

The delay added by the clock delayer 590 is adjusted to the time performance of other logic stage elements. For a low logic output, the clock delay, T_{D}, is preferably long enough to allow logic network 570 to discharge the output node, and for inverter 550 to subsequently go high. On the other hand, for a high logic output, the clock delay is preferably not so long that the output node has time to discharge to a low logic level before the retention device 510 enters strong retention. Note that if the clock delayer 590 provides a constant delay, increasing the period of the logic stage clock, the evaluation region (B-C) stays constant, while the retention (B-D) and precharge regions (A-B) are stretched along with the clock. The constraints on the timing of the delayed clock signal are discussed in more detail below.

To ensure robust performance of the retention device, the clock delay, T_{D}, is not less than the maximum evaluation delay at the worst case corner and operating conditions, so that contention between the retention device 510 and the logic network 570 does not occur. The clock delayer 590 may contain a replica delay line that mimics the worst case delay in the domino data path. If the minimum delay is not sufficiently long the output node cannot discharge, and the retention device 510 will cause the logic stage to fail. Since domino logic stages can be placed one after another and can make up a complete clock phase, the delayed clock preferably has at least one clock phase of delay under worst-case delay conditions.

The delay, T_{D}, provided by clock delayer 590 is preferably small enough to keep the leakage voltage drop within limits over all processing corners and for all operating conditions. The clock delayer 590 preferably tracks with temperature, since leakage current increases with increased temperature whereas saturation current decreases with increased temperature. Generally, voltage and process variations affect leakage current and saturation current roughly equivalently, and are thus relatively easy to compensate for. For a given logic stage, the maximum allowable clock delay is determined by the maximum allowed voltage drop, net capacitance, and transistor leakage in the process and operational conditions. If T_{D} is too long, the voltage drop due to leakage may cause the circuit to fail. Note however, that the constraint on maximum delay is far less strict than the constraints on minimum delay. A maximum delay that exceeds the allowed time will cause the leakage induced voltage drop on the discharge node to increase, but will not necessarily cause the circuit to fail. This is in contrast to some prior art retention devices where failure to meet either timing constraint leads to certain circuit failure.

The dynamic logic stage described above experiences some leakage induced voltage drop at the output node, but the voltage drop does not prevent the development of wide fan-in dynamic logic stages. For example, for current state of the art 130 nm CMOS transistors the worst-case leakage is 400 nA/um and the diffusion capacitance is approximately 1 ff/um for a contacted transistor diffusion. If a 0.2V voltage drop on the output node is acceptable, and given that I=Cdv/dt, an intrinsic leakage process drop of 200 mV per 500 ps is obtained. If more transistors are added to the logic network there is more leakage, but the capacitance also grows proportionally. Note that in the case of leakage, the gate capacitance of the domino inverter and the wire capacitance are beneficial. These calculations show that for the current technology, the present retention device embodiments allow placing a chain of domino gates with up to 500 ps delay in a single phase, to obtain a voltage drop not larger than 200 mV.

The retention device described above has several advantages over the prior art. First, contention between the weak keeper and the logic network is completely eliminated. Secondly, removing the weak keeper reduces the output node capacitance. Simulations show a 10% improvement in timing over the prior art, due to both of these factors. Additionally, the present embodiments provide a retention device which requires less power and area than other prior-art strong retention devices, since the switching element requires only two PMOS transistors. In comparison, Alvandpour's strong retention device requires six PMOS transistors. In terms of area, the present embodiments can save up to 50% for small domino gates, relative to Alvandpour's device.

In the preferred embodiment, the retention device is an integral component of a dynamic logic stage. The dynamic logic stage consists pull-up element 560, logic network 570, and inverter 550, in addition to the retention device 510 described above.

Pull-up element 560 charges the output node during the precharge phase of the clock signal, and releases the output node for evaluation during the evaluate phase. The pull-up device 560 is preferably a transistor, such as an FET (field effect transistor), and is generally a PMOS transistor. For a PMOS transistor pull-up element 560, the precharge phase occurs when the clock is low and the evaluate phase occurs when the clock is high. During the precharge phase, a low voltage applied to the transistor gate connects the pull-up voltage source to the output node. During the evaluate phase, a high voltage applied to the transistor gate disconnects the output node from the pull-up voltage source, so that the output node level is determined by the output of logic network 570.

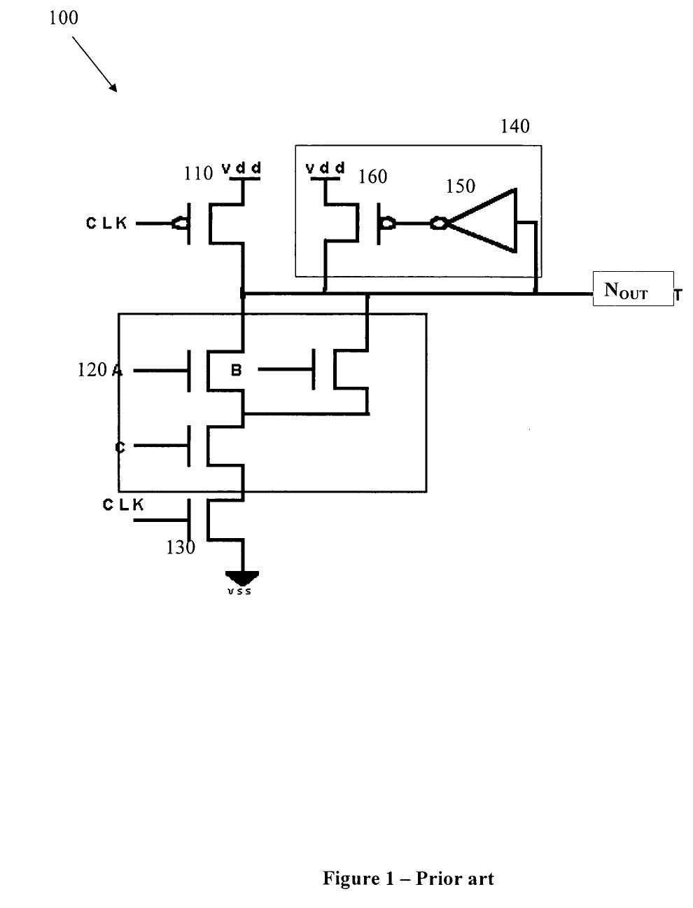

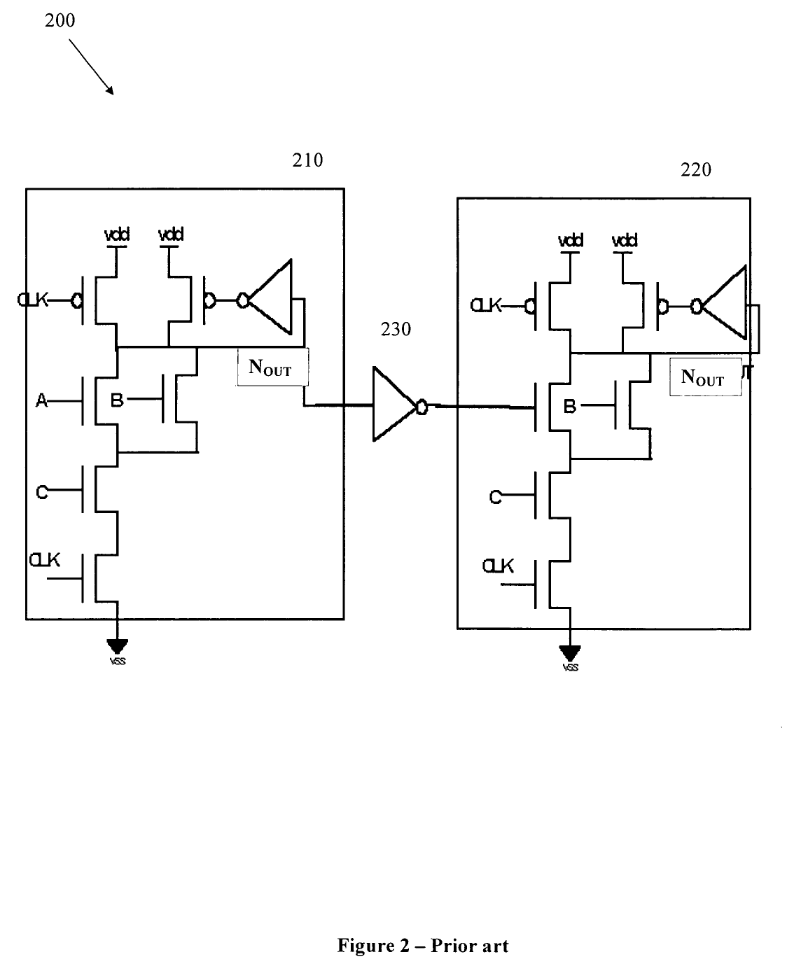

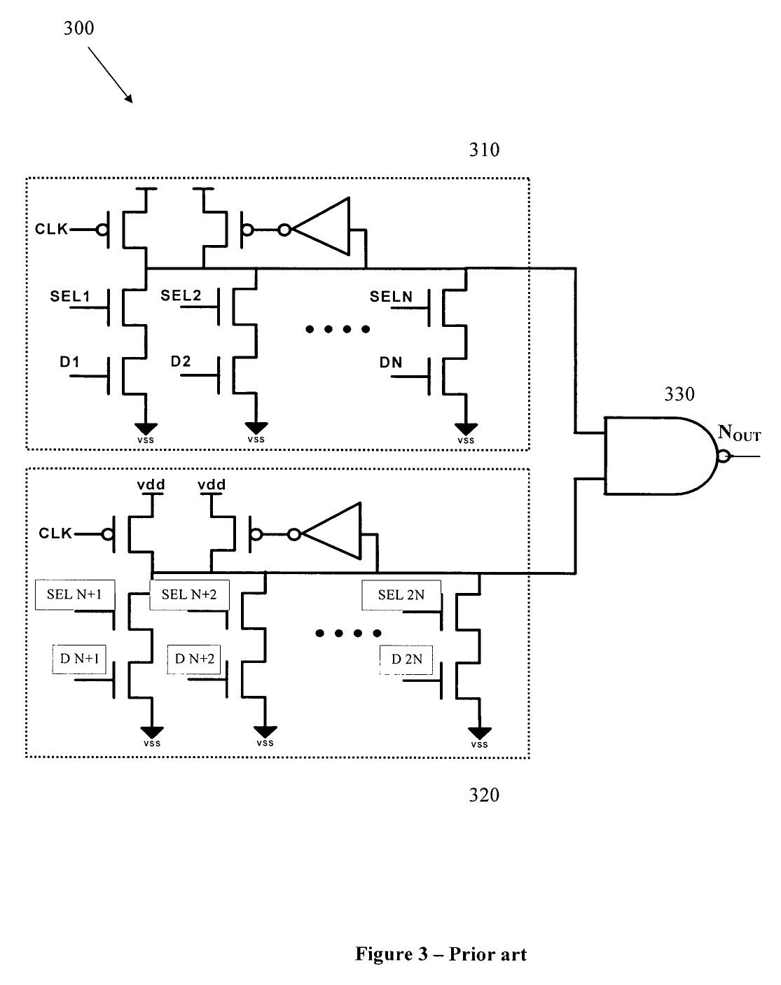

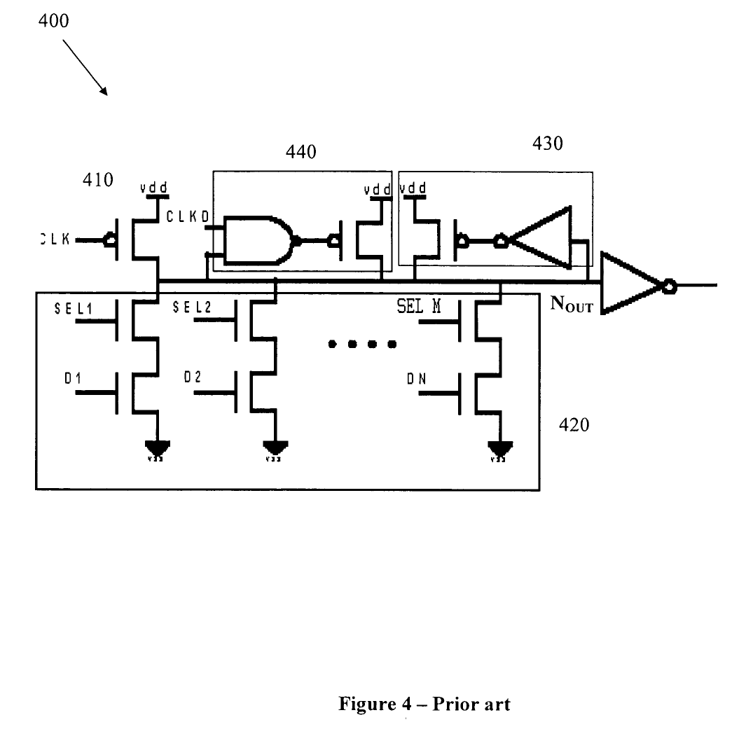

Logic network 570 evaluates the logic inputs in accordance with a specific logic function determined by the arrangement of the logic network components. Logic network 570 is preferably a network of transistors, such as FET transistors, and is generally a network of NMOS transistors interconnected so as to perform the desired logic operation upon the logic input signals. An example of such a logic network is shown in FIG. 1 (logic network 120).

Inverter 550 inverts the logic signal at the output node, to create the feedback signal needed by switching element 520. Note that a single inverter 550 may be used to generate the feedback signal as well as to provide buffering to the next dynamic logic stage. Alternately, a separate inverter may be provided from the output node to the following logic stage.

Preferably logic stage 500 also contains a clock delayer 590, which delays the input clock to generate the delayed clock signal that serves as the control signal for retention device 510. When a clock delayer 590 is not part of the logic stage 500, the delayed clock control signal is provided externally.

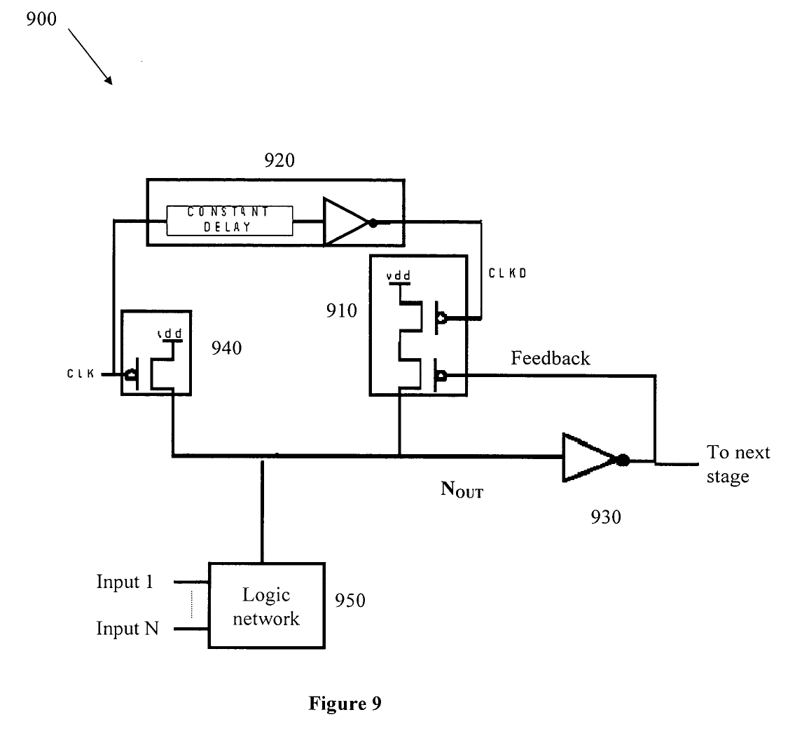

Reference is now made to FIG. 9, which is a simplified block diagram of a dynamic logic stage having an integral retention device, according to a preferred embodiment of the present invention. Logic stage 900 is similar to the preferred embodiment shown in FIG. 5, but has a retention device 910 consisting of two PMOS transistors in series. Each transistor is switched by one of the retention device control signals, the feedback signal and the delayed clock signal. The first PMOS transistor is controlled by the delayed clock signal, CLKD. CLKD is generated by clock delayer 920, consisting of a constant delay element and an inverter in series, which adds a fixed delay to the logic stage clock, CLK. The feedback signal controls the second PMOS transistor. The feedback signal is generated by inverter 930, which inverts the logic output at the logic stage output node, N_{OUT}. The retention device 910 output feeds back into N_{OUT}. An additional PMOS transistor 940 functions as a pull-up element, connecting the output node to V_{DD} whenever the clock signal, CLK, is low, and disconnecting the output node from V_{DD} when CLK is high. Logic network 950 has N logic inputs, and a single logic output connected to the output node. Logic network 950 evaluates the N logic inputs, and outputs the result to N_{OUT}. The resulting logic stage 900 provides a strongly retained dynamic logic output.

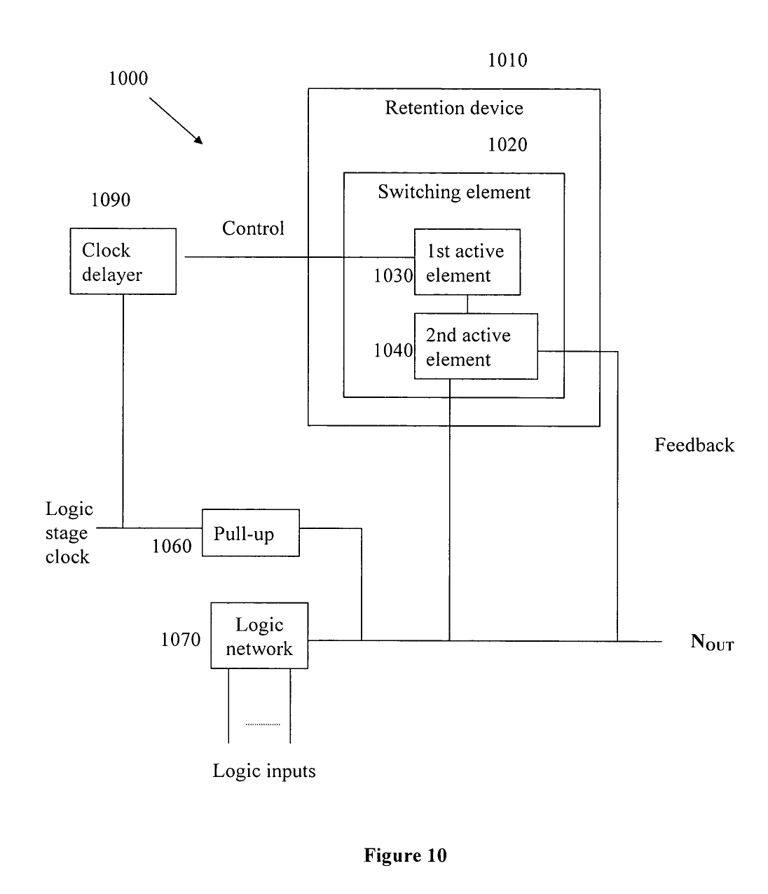

Reference is now made to FIG. 10, which is a simplified block diagram of a retention device for a dynamic logic stage that does not include an inverter, according to a preferred embodiment of the present invention. As shown in FIG. 10, the logic signal at N_{OUT} is fed back directly to retention device 1010, to serve as the feedback control signal for the second active element 1040. In this case, the second active element 1040 switching control operates with reversed polarity compared to the cases described above. That is, active element 1040 is closed when the feedback control signal is high, and is open when the feedback control signal is low. Otherwise the dynamic logic stage of FIG. 10 operates substantially as described above for a dynamic logic stage with an output inverter. The current embodiment is particularly relevant when a dynamic logic stage is not followed by a subsequent stage (i.e. is the final logic stage in the chain), so that no inverter is required for buffering.

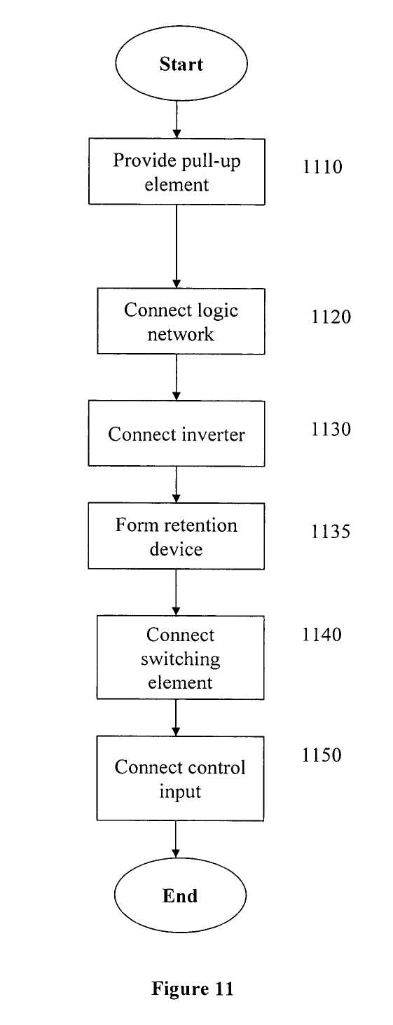

Reference is now made to FIG. 11, which is a simplified flowchart of a method for providing a stabilized dynamic logic stage. The resulting dynamic logic stage contains the basic elements of a dynamic logic stage as well as the retention device described in the above embodiments.

In step 1110 a pull-up element is provided. The pull-up element has a clock input for receiving a clock signal and a pull-up output. In step 1120, the logic network is connected to the pull-up element. The logic element logic output and the pull-up element output are connected together to form the output node. In step 1130, an inverter input is connected to the output node. In step 1135, a switching element is formed by connecting two active elements in series. The switching element has a feedback input, a delayed clock input, and an output. The inverter output is connected in step 1140 to the switching element's feedback input. In step 1140, the switching element is connected between the inverter and the logic network, so that the switching element's feedback input is connected to the output of the inverter, and the switching element's output is connected to the output node. In step 1150 the switching element's control input is connected so that a delayed version of the clock signal can be provided to the control input during operation.

As described above, the switching element contains two active elements connected in series. One or both of these active elements may be a transistor, such as an FET (field effect transistor). Preferably both active elements are PMOS transistors.

The pull-up element preferably consists of a transistor, such as an FET or a PMOS transistor.

The logic network is preferably a network of transistors, such as FET or NMOS transistors, interconnected so as to perform the desired logic operation upon the logic input signals.

In the preferred embodiment the delayed version of the clock signal is provided to the switching element by connecting the output of a clock delayer to the switching element control input. The clock delayer has an input for receiving the logic stage clock signal. The clock delayer may consist of a single inverter, a chain of inverters, transmission gates, or a wire delay line.

The retention device embodiments described above provide faster and more robust dynamic logic circuits. A strongly retained dynamic logic stage can be obtained with a relatively small investment of system area and power resources. Wider fan-in logic stages are possible, since the strongly retained logic output is less affected by leakage currents than are prior art devices. The resulting improved dynamic logic circuits can be used not just for critical paths but for other system elements, thus improving overall system speed and performance.

It is expected that during the life of this patent many relevant active elements, switching elements, transistors, pull-up elements, logic networks, and delay elements, will be developed and the scope of the terms active element, switching element, transistor, pull-up element, logic network, and delay element is intended to include all such new technologies a priori.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable subcombination.

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims. All publications, patents and patent applications mentioned in this specification are herein incorporated in their entirety by reference into the specification, to the same extent as if each individual publication, patent or patent application was specifically and individually indicated in this application shall not be construed as an admission that such reference is available as prior art to the present invention.

1. A retention device for a dynamic logic stage having an output inverter, said retention device being for stabilizing the respective first and second logic output levels of said logic stage, said inverter being connected to provide an inversion of said logic output for use by said retention device as a feedback signal for performing said stabilizing, said retention device comprising:
a switching element comprising a first and a second active elements connected in series;
a control input for receiving a delayed clock signal; and
a feedback input for receiving said inverted logic signal;
therewith to switch between a first and a second retention states in accordance with said feedback and delayed clock signals, said first and second retention states being respectively for stabilizing said first and a second logic output levels.

2. A retention device for a dynamic logic stage according to claim 1, configured to prevent said logic output from discharging from said first logic output level to said second logic output level when in said first retention state.

3. A retention device for a dynamic logic stage according to claim 2, wherein said configuring to prevent comprises providing said first logic output level at an output of said retention device.

4. A retention device for a dynamic logic stage according to claim 1, configured to enable said logic output to discharge from said first logic output level to said second logic output level when in said second retention state.

5. A retention device for a dynamic logic stage according to claim 4, wherein said configuring to enable comprises providing a high impedance at an output of said retention device.

6. A retention device for a dynamic logic stage according to claim 1, wherein said output inverter is further connected to provide a buffered inverted logic signal to a second dynamic logic stage.

7. A retention device for a dynamic logic stage according to claim 1, wherein said first active element is configured to be switched by said delayed clock signal.

8. A retention device for a dynamic logic stage according to claim 1, wherein said second active element is configured to be switched by said feedback signal.

9. A retention device for a dynamic logic stage according to claim 1, further comprising a clock delayer connected between a dynamic logic stage clock input and said control input.

10. A retention device for a dynamic logic stage according to claim 9, wherein said clock delayer comprises an inverter.

11. A retention device for a dynamic logic stage according to claim 9, wherein said clock delayer comprises a chain of inverters.

12. A retention device for a dynamic logic stage according to claim 9, wherein said clock delayer comprises at least one transmission gate.

13. A retention device for a dynamic logic stage according to claim 9, wherein said clock delayer comprises at least one wire delay line.

14. A retention device for a dynamic logic stage according to claim 1, wherein said active elements comprise transistors.

15. A retention device for a dynamic logic stage according to claim 1, wherein said active elements comprise field effect transistors (FETs).

16. A retention device for a dynamic logic stage according to claim 1, wherein said active elements comprise p-type metal oxide semiconductor (PMOS) field effect transistors.

17. A retention device for a dynamic logic stage, said retention device being for stabilizing the respective first and second logic output levels of said logic stage, said retention device comprising:
a switching element comprising a first and a second active elements connected in series;
a control input for receiving a delayed clock signal; and
a feedback input for receiving a feedback signal comprising a logic output signal of said dynamic logic stage;
therewith to switch between a first and a second retention states in accordance with said feedback and delayed clock signals, said first and second retention states being respectively for stabilizing said first and a second logic output levels.

18. A retention device for a dynamic logic stage according to claim 17, configured to prevent said logic output from discharging from said first logic output level to said second logic output level when in said first retention state.

19. A retention device for a dynamic logic stage according to claim 18, wherein said configuring to prevent comprises providing said first logic output level at an output of said retention device.

20. A retention device for a dynamic logic stage according to claim 17, configured to enable said logic output to discharge from said first logic output level to said second logic output level when in said second retention state.

21. A retention device for a dynamic logic stage according to claim 20, wherein said configuring to enable comprises providing a high impedance at an output of said retention device.

22. A stabilized dynamic logic stage, comprising:
a pull-up element, for switching said stabilized dynamic logic stage between a precharge phase and an evaluate phase in accordance with an input clock signal;
a logic network associated with said pull-up element, for providing at a logic output an output logic signal comprising a result of a predefined logic operation performed upon input logic signals;
an inverter associated with said logic output, for generating a feedback signal as an inverse of said output logic signal; and
a retention device associated with said pull-up element, said inverter, and said logic network, said retention device being for stabilizing the respective first and second logic output levels of said logic stage, said retention device comprising:
a switching element comprising a first and a second active elements connected in series;
a control input for receiving a delayed version of said input clock signal; and
a feedback input for receiving said inverted logic signal;
therewith to switch between a first and a second retention states in accordance with said feedback and delayed clock signals, said first and second retention states being respectively for stabilizing said first and a second logic output levels.

23. A stabilized dynamic logic stage according to claim 22, configured to prevent said logic output from discharging from said first logic output level to said second logic output level when in said first retention state.

24. A stabilized dynamic logic stage according to claim 23, wherein said configuring to prevent comprises providing said first logic output level at an output of said retention device.

25. A stabilized dynamic logic stage according to claim 22, configured to enable said logic output to discharge from said first logic output level to said second logic output level when in said second retention state.

26. A stabilized dynamic logic stage according to claim 25, wherein said configuring to enable comprises providing a high impedance at an output of said retention device.

27. A stabilized dynamic logic stage according to claim 22, wherein said pull-up element comprises a transistor.

28. A stabilized dynamic logic stage according to claim 22, wherein said pull-up element comprises an FET.

29. A stabilized dynamic logic stage according to claim 22, wherein said pull-up element comprises a PMOS field effect transistor.

30. A stabilized dynamic logic stage according to claim 22, wherein said logic network comprises a network of transistors.

31. A stabilized dynamic logic stage according to claim 22, wherein said logic network comprises a network of FETs.

32. A stabilized dynamic logic stage according to claim 22, wherein said logic network comprises a network of NMOS field effect transistors.

33. A stabilized dynamic logic stage according to claim 22, wherein said first active element is configured to be switched by said delayed clock signal.

34. A stabilized dynamic logic stage according to claim 22, wherein said second active element is configured to be switched by said feedback signal.

35. A stabilized dynamic logic stage according to claim 22, further comprising a clock delayer connected between a dynamic logic stage clock input and said control input.

36. A stabilized dynamic logic stage according to claim 35, wherein said clock delayer comprises an inverter.

37. A stabilized dynamic logic stage according to claim 35, wherein said clock delayer comprises at least one of a group of delay elements comprising: an inverter, a transmission gate, and a wire delay line.

38. A stabilized dynamic logic stage according to claim 22, wherein said active elements comprise transistors.

39. A stabilized dynamic logic stage according to claim 22, wherein said active elements comprise field effect transistors (FETs).

40. A stabilized dynamic logic stage according to claim 22, wherein said active elements comprise p-type metal oxide semiconductor (PMOS) field effect transistors.

41. A method for providing a stabilized dynamic logic stage comprising:
providing a pull-up element, having a clock input for receiving a clock signal, and a pull-up output;
connecting a logic output of a logic network to said pull-up output, said logic network having a plurality of logic inputs;
connecting an inverter to said logic output and said pull-up element, such that an input of said inverter is connected to said logic output;
forming a switching element by connecting a first and a second active elements in series;
connecting said switching element between said inverter and said logic network, such that a retention output of said switching element is connected to said logic output, and a feedback input of said switching element is connected to an output of said inverter; and
connecting a control input of said switching element to receive a delayed version of said clock signal.

42. A method for providing a stabilized dynamic logic stage according to claim 41, further comprising connecting a delay stage to said clock signal to provide said delayed version of said clock signal.

43. A method for providing a stabilized dynamic logic stage according to claim 42, wherein said delay stage comprises an inverter.

44. A method for providing a stabilized dynamic logic stage according to claim 42, wherein said delay stage comprises a chain of inverters.

45. A method for providing a stabilized dynamic logic stage according to claim 41, wherein said active elements comprise transistors.

46. A method for providing a stabilized dynamic logic stage according to claim 41, wherein said active elements comprise field effect transistors (FETs).

47. A method for providing a stabilized dynamic logic stage according to claim 41, wherein said active elements comprise p-type metal oxide semiconductor (PMOS) field effect transistors.

48. A method for providing a stabilized dynamic logic stage according to claim 41, wherein said pull-up element comprises a transistor.

49. A method for providing a stabilized dynamic logic stage according to claim 48, wherein said pull-up element comprises a FET.

50. A method for providing a stabilized dynamic logic stage according to claim 41, wherein said pull-up element comprises a PMOS field effect transistor.

51. A method for providing a stabilized dynamic logic stage according to claim 41, wherein said logic network comprises a network of transistors.

52. A method for providing a stabilized dynamic logic stage according to claim 41, wherein said logic network comprises a network of FETs.

53. A method for providing a stabilized dynamic logic stage according to claim 41, wherein said logic network comprises a network of NMOS field effect transistors.
